(19) United States
(12) Patent Application Publication
(10) Pub. No.: US 2025/0331397 A1
(43) Pub. Date: Oct. 23, 2025

(54) DISPLAY DEVICE AND METHOD OF MANUFACTURING THE SAME

(71) Applicant: Samsung Display Co., Ltd., Yongin-si (KR)

(72) Inventors: DONGGEUN SHIN, Yongin-si (KR); KYUNG-MAN KIM, Yongin-si (KR); TAEMIN KIM, Yongin-si (KR); KYUNGHEE LEE, Yongin-si (KR); SEUNGHEE LEE, Yongin-si (KR)

(21) Appl. No.: 19/091,699

(22) Filed: Mar. 26, 2025

(30) Foreign Application Priority Data
Apr. 22, 2024 (KR) 10-2024-0053559

(51) Int. Cl. H10K 59/80; G02B 27/01; H10K 59/12; H10K 59/38; H10K 102/00

(52) U.S. Cl. CPC H10K 59/873; G02B 27/0172; H10K 59/1201; H10K 59/38; H10K 59/879; G02B 2027/0132; H10K 2102/351

(57) ABSTRACT

A display device includes a display area and a peripheral area adjacent to the display area. The display device includes a base layer, a display element layer on the base layer and including a light emitting element that overlaps the display area when viewed in a plane, a color filter on the display element layer, a refractive layer on the color filter, and a protective layer on the refractive layer. The refractive layer includes a cover layer that covers the color filter and a convex pattern between the cover layer and the protective layer and provided integrally with the cover layer. One end of the protective layer is aligned with a boundary between the display area and the peripheral area when viewed in the plane.

### CROSS-REFERENCE TO RELATED APPLICATION(S)

The present application claims priority to and the benefit of Korean Patent Application No. 10-2024-0053559, filed on Apr. 22, 2024, in the Korean Intellectual Property Office, the entire content of which is hereby incorporated by reference.

### BACKGROUND

### 1. Field

Embodiments of the present disclosure relate to a display device and a method of manufacturing the same. For example, embodiments of the present disclosure relates to a display device having improved durability and reliability and a method of manufacturing the display device with an improved level of processing difficulty (e.g., reduced processing difficulty).

### 2. Description of Related Art

A display device, such as a television set, a monitor, a smart phone, and a tablet computer, that provide images to a user, includes a display panel. Various display panels, such as a liquid crystal display panel, an organic light emitting display panel, an electrowetting display panel, an electrophoretic display panel, etc., are being developed as display panels.

Research is being conducted on a method of patterning a light emitting element to improve reliability of the display panel, and recently, research on a high-resolution display device that includes a light emitting material generally provided using an open mask is being carried out. For example, a method to improve durability of an ultra-high resolution display device including a micro-lens array (MLA) would be beneficial.

### SUMMARY

Embodiments of the present disclosure provide a display device having high resolution and improved durability and reliability.

Embodiments of the present disclosure provide a method of manufacturing the display device with an improved level of processing difficulty (e.g., reduced processing difficulty).

Embodiments of the present disclosure provide an electronic apparatus including a display area and a peripheral area adjacent to the display area. The electronic apparatus includes a base layer, a display element layer on the base layer and including a light emitting element that overlaps the display area when viewed in a plane (e.g., in a plan view), a color filter on the display element layer, a refractive layer on the color filter, and a protective layer on the refractive layer. The refractive layer includes a cover layer that covers the color filter and a convex pattern between the cover layer and the protective layer and provided integrally with the cover layer. One end of the protective layer is aligned with a boundary between the display area and the peripheral area when viewed in the plane (e.g., in a plan view).

The electronic apparatus further may further include a filling layer on the base layer and that overlaps the protective layer in a first direction.

The filling layer may be in contact with the one end of the protective layer.

The protective layer may have a thickness equal to or greater than about 20 micrometers and equal to or smaller than about 500 micrometers.

The electronic apparatus may further include a window on the protective layer and a sealing member between the base layer and the window, and the protective layer may be spaced apart from the sealing member in the first direction.

The convex pattern may overlap the light emitting element when viewed in the plane (e.g., in a plan view).

The light emitting element may be provided in plural (e.g., as a plurality), and the convex pattern may be provided in plural (e.g., as a plurality).

The refractive layer may have a refractive index equal to or greater than about 1.6.

The refractive layer may include an acrylic resin.

The display area may include a first display area and a second display area spaced apart from the first display area when viewed in the plane (e.g., in a plan view), and each of the first and second display areas may have a quadrangular shape or a circular shape (e.g., a generally circular shape).

The light emitting element may include a first electrode, a light emitting layer on the first electrode, and a second electrode on the light emitting layer.

Embodiments of the present disclosure provide a electronic apparatus including a display area and a peripheral area adjacent to the display area. The electronic apparatus includes a base layer, a display element layer on the base layer and including a light emitting element that overlaps the display area when viewed in a plane (e.g., in a plan view), a color filter on the display element layer, a refractive layer on the color filter, and a protective layer on the refractive layer. The refractive layer includes a cover layer that covers the color filter and a convex pattern between the cover layer and the protective layer and provided integrally with the cover layer. The protective layer includes a first compound including at least one selected from among a polysilsesquioxane-based compound, a polyurethane-based compound, a polycarbonate-based compound, and a polyethylene terephthalate-based compound, a second compound including a surfactant including at least one selected from among a fluorine-containing compound and a silicon-containing compound, and a third compound including an epoxy-based compound, and a weight of the second compound is about 0.05% or more but less than 0.2% of a sum of a weight of the first compound, the weight of the second compound, and a weight of the third compound.

One end of the protective layer may be aligned with a boundary between the display area and the peripheral area when viewed in the plane (e.g., in a plan view).

The first compound may include at least one selected from among a first polysilsesquioxane-based compound to a seventh polysilsesquioxane-based compound respectively represented by the following Formula 1 to Formula 7,

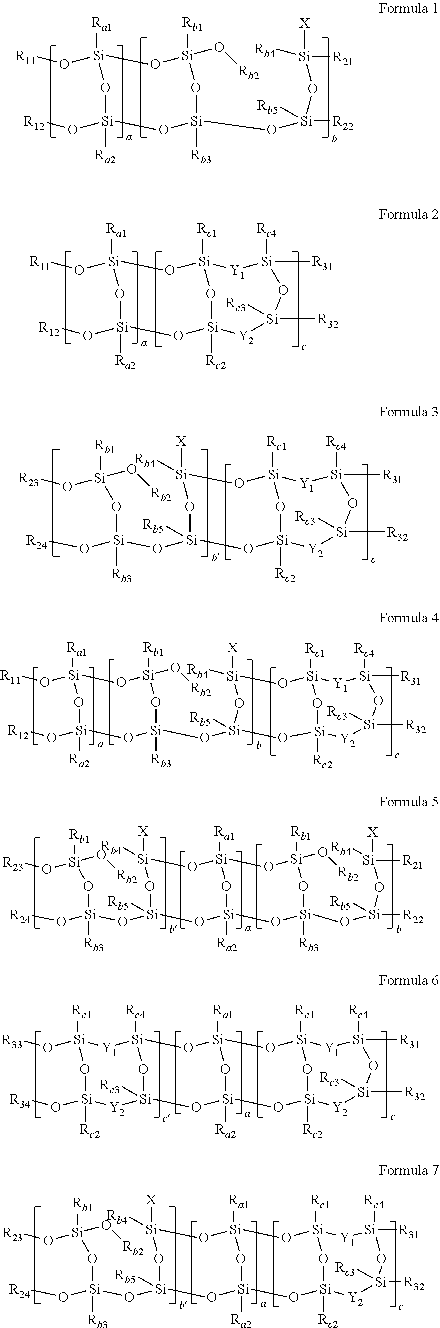

wherein, in Formula 1 to Formula 7, X may be R₄₁ or [SiO_{3/2}R_{42 4+2n}O], Y₁ and Y₂ may each independently be O, NR₅₁, or [SiO_{3/2}R_{52 4+2n′}O], and R₁₁, R₁₂, R₂₁ to R₂₄, R₃₁ to R₃₄, Rₐ₁, Rₐ₂, R_{b1} to R_{b5}, R_{c1} to R_{c4}, R₄₁, R₄₂, R₅₁, and R₅₂ may each independently be a hydrogen atom, a deuterium atom, a halogen atom, a substituted or unsubstituted amino group, a substituted or unsubstituted epoxy group, a nitro group, a nitrile group, a thiol group, an isocyanate group, a substituted or unsubstituted alkyl group having 1 to 20 carbon, a substituted or unsubstituted alkenyl group having 2 to 20 carbon atoms, a substituted or unsubstituted alkoxy group having 1 to 40 carbon, a substituted or unsubstituted heterocyclic group having 2 to 30 ring-forming carbon atoms, a substituted or unsubstituted aryl group having 6 to 30 ring-forming carbon atoms, a substituted or unsubstituted heteroaryl group having 2 to 30 ring-forming carbon atoms, a substituted or unsubstituted aryloxy group having 3 to 30 ring-forming carbon atoms, or a substituted or unsubstituted arylthiol group having 3 to 30 ring-forming carbon atoms, n and n′ are each independently an integer equal to or greater than 1 and equal to or smaller than 20, a is an integer equal to or greater than 1 and equal to or smaller than 100000, and b, b′, c, and c′ are each independently an integer equal to or greater than 1 and equal to or smaller than 100.

The epoxy-based compound may include a viscosity modifier.

Embodiments of the present disclosure provide a method of manufacturing an electronic apparatus. The method includes providing a preliminary display device including a display area and a peripheral area adjacent to the display area and including a base layer, a display element layer on the base layer and including a light emitting element that overlaps the display area when viewed in a plane (e.g., in a plan view), and a color filter on the display element layer, forming a preliminary refractive layer on the color filter, and etching a portion of the preliminary refractive layer to form a refractive layer, and forming a protective layer on the refractive layer. The refractive layer includes a cover layer that covers the color filter and a convex pattern between the cover layer and the protective layer and provided integrally with the cover layer. One end of the protective layer is aligned with a boundary between the display area and the peripheral area when viewed in the plane (e.g., in a plan view).

The forming of the protective layer may include forming a preliminary protective layer including a first compound, a second compound, and a third compound using an inkjet coating method and curing the preliminary protective layer. The first compound may include at least one selected from among a polysilsesquioxane-based compound, a polyurethane-based compound, a polycarbonate-based compound, and a polyethylene terephthalate-based compound, the second compound may include a surfactant including at least one selected from among a fluorine-containing compound and a silicon-containing compound, the third compound may include an epoxy-based compound, and a weight of the second compound may be about 0.05% or more but less than 0.2% of a sum of a weight of the first compound, the weight of the second compound, and a weight of the third compound.

The preliminary protective layer may have a viscosity of about 1 cP or more and about 30 cP or less at about 20 degrees Celsius.

The preliminary refractive layer may have a young's modulus equal to or greater than about 1 GPa and equal to or smaller than about 10 GPa at about 25 degrees Celsius.

The weight of the second compound may be about 0.05% or more and about 0.1% or less of the sum of the weight of the first compound, the weight of the second compound, and the weight of the third compound.

According to the electronic apparatus, the protective layer (e.g., a planarization layer) on a micro-lens array does not include a dam, and thus, the productivity of the electronic apparatus is improved (e.g., production of the electronic apparatus may be increased). According to embodiments of the method of manufacturing the electronic apparatus, the dam is not required in a process of forming the planarization layer on the micro-lens array, and thus, the level of difficulty in manufacturing the electronic apparatus is improved (e.g., reduced), and the productivity of the electronic apparatus is improved (e.g., production of the electronic apparatus may be increased).

### BRIEF DESCRIPTION OF THE DRAWINGS

The above and other features of embodiments of the present disclosure will become readily apparent by reference to the following detailed description when considered in conjunction with the accompanying drawings wherein:

FIG. 1 is an exploded perspective view of an electronic apparatus according to an embodiment of the present disclosure;

FIG. 2 is a perspective view of a display device according to an embodiment of the present disclosure;

FIG. 3 is a cross-sectional view taken along a line I-I′ of FIG. 2;

FIG. 4 is an enlarged view of a portion of the display device of FIG. 3;

FIGS. 5A-5B are flowcharts illustrating a method of manufacturing a display device according to an embodiment of the present disclosure; and

FIGS. 6-11 are cross-sectional views illustrating processes of a method of manufacturing a display device according to an embodiment of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components may be exaggerated for effective description of the technical content. As used herein, the term “and/or” may include any and all combinations of one or more of the associated listed items.

It will be understood that, although the terms first, second, etc. may be used herein to describe various suitable elements, these elements should not be limited by these terms. These terms are only used to distinguish one element from another element. Thus, a first element discussed below could be termed a second element without departing from the spirit and scope of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

In the present disclosure, when an element is referred to as being “directly on” another element, there are no intervening elements present between a layer, film region, or substrate and another layer, film, region, or substrate. For example, the term “directly connected” may mean that two layers or two members are provided without employing additional adhesive therebetween.

In the present disclosure, “substituted or unsubstituted” may mean unsubstituted or substituted with one or more substituents selected from the group consisting of a deuterium atom, a halogen atom, a cyano group, a nitro group, a hydroxyl group, an amino group, an amine group, a silyl group, an oxy group, a thiol group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents described above may be substituted or unsubstituted. For example, a biphenyl group may be interpreted as the aryl group or may be interpreted as a phenyl group substituted with a phenyl group.

In the present disclosure, the description of forming a ring by combining adjacent groups with each other may mean forming a substituted or unsubstituted hydrocarbon ring or a substituted or unsubstituted heterocycle by combining adjacent groups with each other. The hydrocarbon ring may include an aliphatic hydrocarbon ring and an aromatic hydrocarbon ring. The heterocycle may include an aliphatic heterocycle and an aromatic heterocycle. The hydrocarbon ring and heterocycle may be a monocycle or polycycle. In some embodiments, the ring formed by combining adjacent groups with each other may be connected with another ring to form a spiro structure.

In the present disclosure, “an adjacent group” may mean a substituent at an atom which is directly connected with another atom at which a corresponding substituent is substituted, another substituent at an atom at which a corresponding substituent is substituted, or a substituent stereoscopically provided at the nearest position to a corresponding substituent. For example, two methyl groups in 1,2-dimethylbenzene may be interpreted as “adjacent groups”, and two ethyl groups in 1,1-diethylcyclopentane may be interpreted as “adjacent groups”. In some embodiments, two methyl groups in 4,5-dimethylphenanthrene may be interpreted as “adjacent groups”.

In the present disclosure, examples of a halogen atom include a fluorine atom, a chlorine atom, a bromine atom, and an iodine atom.

In the present disclosure, the alkyl group may have a linear or branched form. The carbon number of the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyl eicosyl group, a 2-butyl eicosyl group, a 2-hexyl eicosyl group, a 2-octyl eicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., however, embodiments should not be limited thereto or thereby.

In the present disclosure, a cycloalkyl group may refer to a cyclic alkyl group. The number of carbon atoms in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., however, embodiments should not be limited thereto or thereby.

In the present disclosure, the alkenyl group may be a hydrocarbon group that includes at least one carbon-carbon double bond at a main chain (e.g., in the middle) or at a terminus (e.g., a terminal end) of an alkyl group having 2 or more carbon atoms. The alkenyl group may be linear or branched. The number of carbon atoms in the alkenyl group should not be particularly limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., however, embodiments should not be limited thereto or thereby.

In the present disclosure, the alkynyl group may be a hydrocarbon group that includes at least one carbon-carbon triple bond at a main chain (e.g., in the middle) or at a terminus (e.g., a terminal end) of an alkyl group having 2 or more carbon atoms. The alkynyl group may be linear or branched. The number of carbon atoms in the alkynyl group should not be particularly limited, but may be 2 to 30, 2 to 20, or 2 to 10. Examples of the alkynyl group may include an ethynyl group, a propynyl group, etc., however, embodiments should not be limited thereto or thereby.

In the present disclosure, the hydrocarbon ring group may be any suitable functional group or substituent derived from an aliphatic hydrocarbon ring. For example, the hydrocarbon ring group may be a saturated hydrocarbon ring group having 5 to 20 ring-forming carbon atoms.

In the present disclosure, the aryl group may be any suitable functional group or substituent derived from an aromatic hydrocarbon ring. The aryl group may be monocyclic or polycyclic. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., however, embodiments should not be limited thereto or thereby.

In the present disclosure, the fluorenyl group may be substituted, and two substituents may be bonded to each other to form a spiro structure. Examples of the substituted fluorenyl group are as follows. However, embodiments should not be limited thereto.

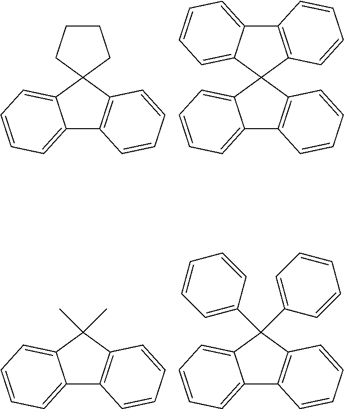

In the present disclosure, the heterocyclic group may be any suitable functional group or substituent derived from a ring that includes at least one selected from among B, O, N, P, Si, and S as a heteroatom. The heterocyclic group may be an aliphatic heterocyclic group or an aromatic heterocyclic group. The aromatic heterocyclic group may be a heteroaryl group. An aliphatic heterocycle or an aromatic heterocycle may each independently be monocyclic or polycyclic.

In the present disclosure, the heterocyclic group may include at least one selected from among B, O, N, P, Si, and S as a heteroatom. When the heterocyclic group contains two or more heteroatoms, the two or more heteroatoms may be the same as or different from each other. The heterocyclic group may be monocyclic or polycyclic, and the heterocyclic group may be a heteroaryl group. The number of ring-forming carbon atoms in the heterocyclic group may be 2 to 30, 2 to 20, or 2 to 10.

In the present disclosure, the aliphatic heterocyclic group may include at least one selected from among B, O, N, P, Si, or S as a heteroatom. The number of ring-forming carbon atoms in an aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., however, embodiments should not be limited thereto or thereby.

In the present disclosure, the heteroaryl group may include at least one selected from among B, O, N, P, Si, or S as a heteroatom. When the heteroaryl group includes two or more heteroatoms, the two or more heteroatoms may be the same as or different from each other. The heteroaryl group may be monocyclic or polycyclic. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., however, embodiments should not be limited thereto or thereby.

In the present disclosure, the above description of the aryl group may be applied to an arylene group, except that the arylene group is a divalent group. In the present disclosure, the above description of the heteroaryl group may be applied to a heteroarylene group, except that the heteroarylene group is a divalent group.

In the present disclosure, the silyl group may be an alkyl silyl group and/or an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments should not be limited thereto.

In the present disclosure, the number of carbon atoms in the acyl group should not be particularly limited, but may be 1 to 40, 1 to 30, 1 to 20, or 1 to 10. Examples of the acyl group may include acetyl, ethylcarbonyl, isopropylcarbonyl, naphthalenecarbonyl, cyclopentylcarbonyl, cyclohexylcarbonyl, phenylcarbonyl, etc., but embodiments should not be limited thereto. As an example, the acyl group may have a structure as follows, however, embodiments should not be limited thereto.

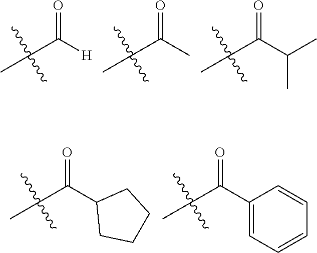

In the present disclosure, the number of carbon atoms in the sulfinyl group or in the sulfonyl group should not be particularly limited, but may be 1 to 30. The sulfinyl group may include an alkyl sulfinyl group and/or an aryl sulfinyl group. The sulfonyl group may include an alkyl sulfonyl group and/or an aryl sulfonyl group. In the present disclosure, the thio group may be an alkylthio group and/or

an arylthio group. The thio group may be a sulfur atom that is bonded to the alkyl group and/or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments should not be limited thereto.

In the present disclosure, the oxy group may be an oxygen atom that is bonded to the alkyl group and/or the aryl group as defined herein. The oxy group may include an alkoxy group and/or an aryl oxy group. The alkoxy group may be linear, branched, or cyclic. The number of carbon atoms in the alkoxy group should not be particularly limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments should not be limited thereto.

In the present disclosure, the boron group may be a boron atom that is bonded to the alkyl group and/or to the aryl group as defined above. The boron group may include an alkyl boron group and/or an aryl boron group. Examples of the boron group may include a dimethylboron group, a diethylboron group, a t-butyldimethylboron group, a diphenylboron group, a phenylboron group, etc., but embodiments should not be limited thereto.

In the present disclosure, the number of carbon atoms in the amine group should not be particularly limited, but may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, etc., but embodiments should not be limited thereto.

In the present disclosure, an alkyl group in an alkylthio group, an alkylsulfoxy group, an alkylaryl group, an alkylamino group, an alkyl boron group, an alkyl silyl group, or an alkyl amine group may be the same as the example of the alkyl group as described above.

In the present disclosure, an aryl group in an aryloxy group, an arylthio group, an arylsulfoxy group, an arylamino group, an arylboron group, an arylsilyl group, or an arylamine group may be the same as the example of the aryl group as described above.

In the present disclosure, a direct linkage may be a single bond (e.g., a single covalent bond).

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to the accompanying drawings.

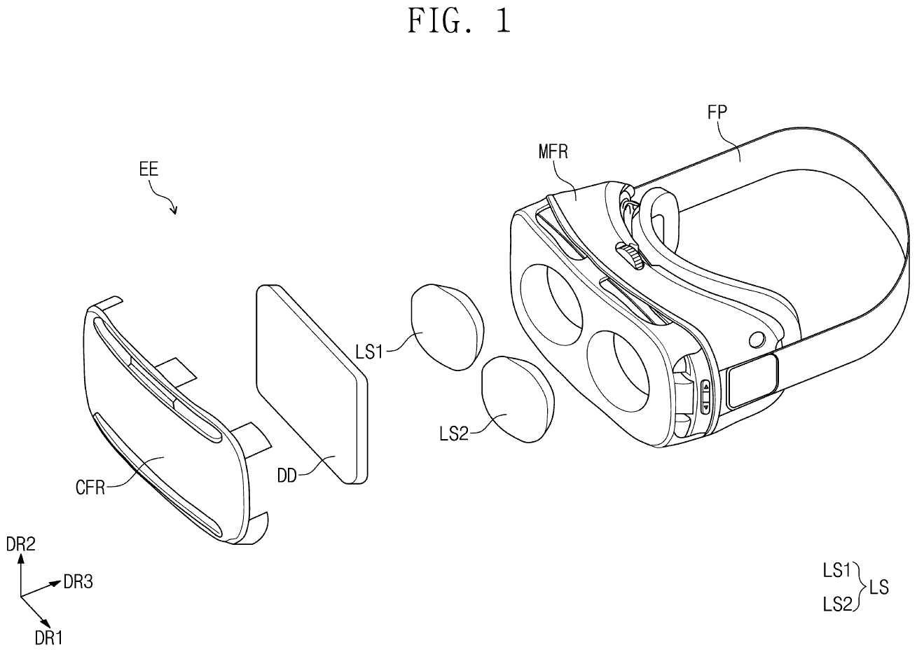

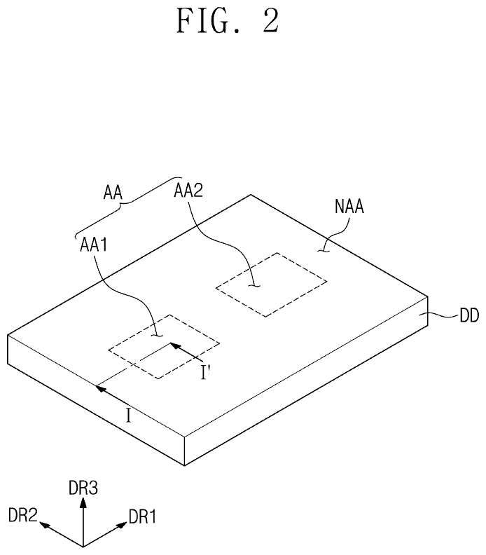

FIG. 1 is an exploded perspective view of an electronic apparatus EE according to an embodiment of the present disclosure. FIG. 2 is a perspective view of a display device DD according to an embodiment of the present disclosure. FIG. 2 shows only the display device DD shown in FIG. 1.

FIG. 1 shows a head-mounted display (HMD) as a representative example of the electronic apparatus EE. The head-mounted display may be an electronic apparatus that is worn on the head of a user and provides a screen on which an image and/or video is displayed to the user. The head-mounted display may include a see-through type (or kind of) head-mounted display that provides an augmented reality (AR) based on actual external objects and a see-closed type (or kind of) head-mounted display that provides a virtual reality (VR) to the user with images independent from the external objects.

Referring to FIG. 1, the electronic apparatus EE may include the display device DD and a lens part LS facing the display device DD. In some embodiments, the electronic apparatus EE may include a main frame MFR, a cover frame CFR, and a fixing part FP.

The main frame MFR may be a part worn on the face of the user. The main frame MFR may have a shape corresponding to a shape of the head (face) of the user. As an example, a length of the fixing part FP may be adjusted according to a periphery or circumference of the user's head. The fixing part FP may be a structure that facilitates the installation of the main frame MFR and may include straps, bands, and/or the like, however, the present disclosure should not be limited thereto or thereby. According to an embodiment, the fixing part FP may have various suitable shapes, such as helmets or eyeglass temples, that are combined with the main frame MFR.

The main frame MFR may be coupled with the cover frame CFR to provide an accommodating space in which the lens part LS and the display device DD are accommodated.

The lens part LS may be between the display device DD and the user. The lens part LS may transmit a light emitted from the display device DD and may provide the light to the user. As an example, the lens part LS may include various suitable types (or kinds) of lenses, such as multi-channel lenses, convex lenses, concave lenses, spherical lenses, aspherical lenses, simple lenses, compound lenses, standard lenses, narrow-angle lenses, wide-angle lenses, fixed-focal lenses, and/or varifocal lenses.

The lens part LS may include a first lens LS1 and a second lens LS2. The first lens LS1 and the second lens LS2 may be provided to correspond to positions of the user's left and right eyes, respectively. The first lens LS1 and the second lens LS2 may be accommodated in the main frame MFR.

The display device DD may be provided in a state fixed to the main frame MFR or may be provided in a state detachable from the main frame MFR. The display device DD may provide an image to the user, and the image may include a still image as well as a video. The display device DD will be described in more detail herein.

The cover frame CFR may be on one surface of the display device DD and may protect the display device DD. The cover frame CFR and the lens part LS may be spaced apart from each other with the display device DD interposed therebetween.

In FIG. 1 and the following drawings, first, second, and third directions DR1, DR2, and DR3 are shown, and directions indicated by the first, second, and third directions DR1, DR2, and DR3 in the following descriptions are relative to each other, and thus, the directions indicated by the first, second, and third directions DR1, DR2, and DR3 may be changed to other directions. In the following descriptions, the first direction DR1 and the second direction DR2 may be perpendicular (or substantially perpendicular) to each other, and the third direction DR3 may be a normal line direction with respect to a plane defined by the first direction DR1 and the second direction DR2.

A thickness direction of the electronic apparatus EE may be substantially parallel to the third direction DR3 that is the normal line direction with respect to the plane defined by the first direction DR1 and the second direction DR2. In the present embodiment, front (or upper) and rear (or lower) surfaces of each member of the electronic apparatus EE may be distinguished from each other with respect to the third direction DR3. In the following descriptions, the expression “when viewed in a plane” (or “in a plan view”) may mean a state of being viewed in the third direction DR3 parallel to the plane defined by the first direction DR1 and the second direction DR2, and the expression “when viewed in a cross-section” may mean a state of being viewed in the first direction DR1 or the second direction DR2.

Referring to FIG. 2, the display device DD may have a configuration substantially generating the image. The image generated by the display device DD may be viewed by the user from the outside.

The display device DD may be a light emitting type (or kind of) display device, however, it should not be particularly limited. For instance, the display device DD may be an organic light emitting display device and/or an inorganic light emitting display device. The organic light emitting display device may be a display device in which a light emitting layer includes an organic light emitting material. The inorganic light emitting display device may be a display device in which a light emitting layer includes a quantum dot, a quantum rod, and/or a micro-LED. Hereinafter, the organic light emitting display device will be described as the display device DD.

The display device DD may include a display area AA and a peripheral area NAA.

The display device DD may display the image through the display area AA. The display area AA may include the plane defined by the first direction DR1 and the second direction DR2. The display area AA may be provided in plural (e.g., as a plurality). The display area AA may include a first display area AA1 and a second display area AA2. FIG. 2 shows a structure in which the first display area AA1 and the second display area AA2 are spaced apart from each other in the first direction DR1 as a representative example, however, the present disclosure should not be limited thereto or thereby. According to an embodiment, one, two, three, or more display areas AA may be defined in the display device DD. The display area AA may have a quadrangular shape or a circular shape (or a generally circular shape). Each of the first display area AA1 and the second display area AA2 may have a quadrangular shape or a circular shape (or a generally circular shape). As an example, as shown in FIG. 2, each of the first display area AA1 and the second display area AA2 may have a quadrangular shape. The peripheral area NAA may be defined adjacent to the display area AA. The peripheral area NAA may surround the display area AA. The peripheral area NAA may be defined adjacent to each of the first display area AA1 and the second display area AA2. The peripheral area NAA may surround each of the first display area AA1 and the second display area AA2, however, the present disclosure should not be limited thereto or thereby. According to an embodiment, the peripheral area NAA may be adjacent to only one side of the display area AA.

Referring to FIGS. 1-2, the display area AA may correspond to the lens part LS. The first display area AA1 may correspond to the first lens LS1. The second display area AA2 may correspond to the second lens LS2. A light emitted from the first display area AA1 may be incident to the user's left eye through the first lens LS1. A light emitted from the second display area AA2 may be incident to the user's right eye through the second lens LS2.

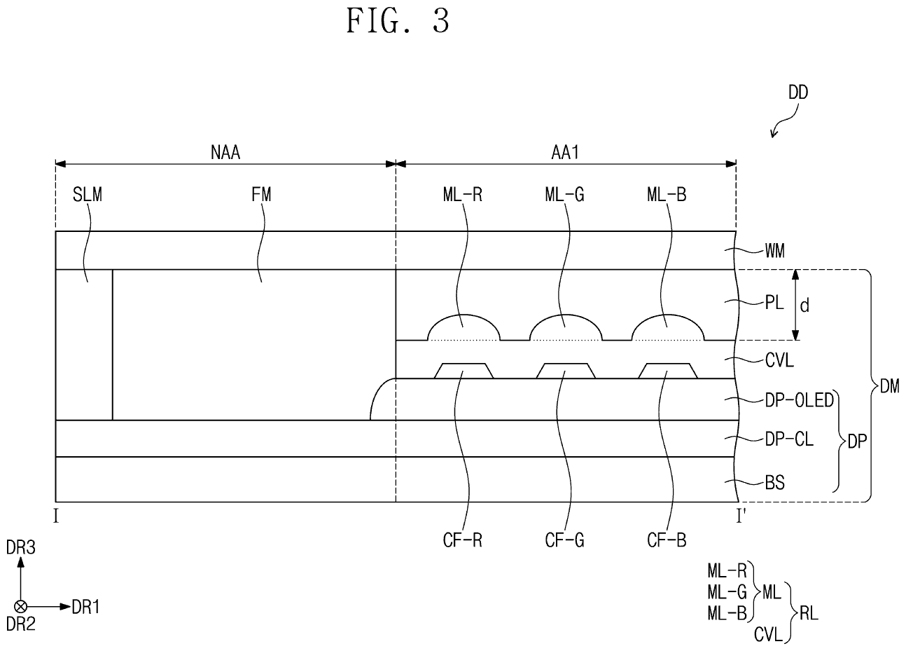

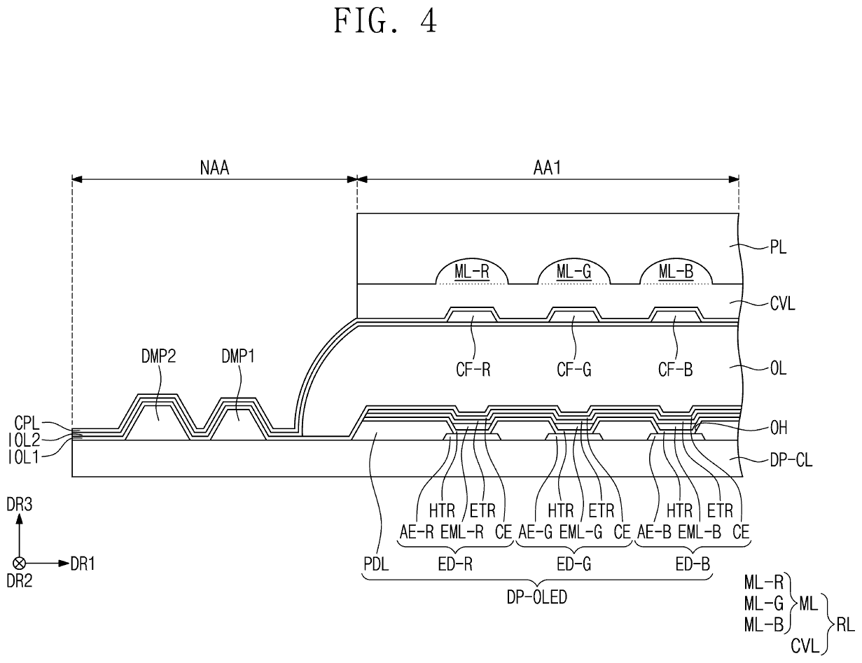

FIG. 3 is a cross-sectional view taken along a line I-I′ of FIG. 2. FIG. 4 is an enlarged view of a portion of the display device DD of FIG. 3. In FIG. 4, a base layer BS, a filling layer FM, a sealing member SLM, and a window WM shown in FIG. 3 are omitted, and a stacked structure of the display device DD is shown in more detail.

Referring to FIGS. 3-4, the display device DD may include the base layer BS, a display element layer DP-OLED, color filters CF-R, CF-G, and CF-B, a refractive layer RL, and a protective layer PL. A display panel DP may include the base layer BS and the display element layer DP-OLED. A display module DM may include the display panel DP, the color filters CF-R, CF-G, and CF-B on the display panel DP, the refractive layer RL on the display panel DP to cover the color filters CF-R, CF-G, and CF-B, and the protective layer PL on the refractive layer RL.

The base layer BS may be a member that provides a base surface on which the display element layer DP-OLED is provided. The base layer BS may be rigid or flexible. The base layer BS may be a glass substrate, a metal substrate, and/or a polymer substrate, however, it should not be limited thereto or thereby. According to an embodiment, the base layer BS may be an inorganic layer including an inorganic material, an organic layer including an organic material, or a composite material layer including an inorganic material and an organic material.

The base layer BS may have a single-layer or multi-layer structure. For instance, the base layer BS may have a three-layer structure of a polymer resin layer, an adhesive layer, and a polymer resin layer. The polymer resin layers may include a polyimide-based resin. In some embodiments, the polymer resin layers may include at least one selected from among an acrylic-based resin, a vinyl-based resin, an epoxy-based resin, a urethane-based resin, a cellulose-based resin, a siloxane-based resin, and a perylene-based resin. In some embodiments of the present disclosure, the term “X-based resin”, as used herein, refers to the resin that includes a functional group of X.

The display panel DP may further include a circuit layer DP-CL between the base layer BS and the display element layer DP-OLED. The circuit layer DP-CL may be on the base layer BS. The circuit layer DP-CL may include an insulating layer (e.g., an electrically insulating layer), a semiconductor pattern, a conductive pattern (e.g., an electrically conductive pattern), and a signal line. The circuit layer DP-CL may include a plurality of transistors formed of the semiconductor pattern, the conductive pattern, and the signal line. Each of the transistors may include a control electrode, an input electrode, and an output electrode. As an example, the circuit layer DP-CL may include a switching transistor and a driving transistor to drive a light emitting elements ED-R, ED-G, and ED-B.

The display element layer DP-OLED may be above the base layer BS. The display element layer DP-OLED may be on the circuit layer DP-CL. The display element layer DP-OLED may include light emitting elements ED-R, ED-G, and ED-B. The display element layer DP-OLED may include a first light emitting element ED-R, a second light emitting element ED-G, and a third light emitting element ED-B. The display element layer DP-OLED may further include a pixel definition layer PDL. The light emitting elements ED-R, ED-G, and ED-B may overlap the display area AA when viewed in the plane (e.g., in a plan view). Each of the light emitting elements ED-R, ED-G, and ED-B may include a corresponding first electrode among first electrodes AE-R, AE-G, and AE-B, a second electrode CE facing the corresponding first electrode among the first electrodes AE-R, AE-G, and AE-B, and a corresponding light emitting layer among light emitting layers EML-R, EML-G, and EML-B between the first electrodes AE-R, AE-G, and AE-B and the second electrode CE. In some embodiments, each of the light emitting elements ED-R, ED-G, and ED-B may further include a hole transport region HTR and an electron transport region ETR.

In some embodiments of the present disclosure, the term “overlap” between two components should not be limited to having the same size and the same shape when viewed in the plane (e.g., in a plane view) and may include cases where the two components have different sizes and/or different shapes. The plane may be perpendicular (or substantially perpendicular) to the thickness direction.

The pixel definition layer PDL may be on the base layer BS. The pixel definition layer PDL may be on the circuit layer DP-CL. The pixel definition layer PDL may be provided with a plurality of pixel openings OH defined therethrough. At least a portion of each of the first electrodes AE-R, AE-G, and AE-B may be exposed through the pixel openings OH of the pixel definition layer PDL.

The pixel definition layer PDL may include an organic resin and/or an inorganic material. As an example, the pixel definition layer PDL may include a polyacrylate-based resin, a polyimide-based resin, silicon nitride (SiNₓ), silicon oxide (SiOₓ), and/or silicon oxynitride (SiOₓN_{y}).

The pixel definition layer PDL may have a light absorbing property. For example, the pixel definition layer PDL may have a black color. The pixel definition layer PDL may include a black coloring agent. The black coloring agent may include a black dye and/or a black pigment. The pixel definition layer PDL may correspond to a light blocking pattern having a light blocking property.

FIG. 4 shows a structure in which the light emitting layers EML-R, EML-G, and EML-B of the light emitting elements ED-R, ED-G, and ED-B are provided in the pixel openings OH defined through the pixel definition layer PDL and the hole transport region HTR, the electron transport region ETR, and the second electrode CE are commonly provided in the light emitting elements ED-R, ED-G, and ED-B. However, the present disclosure should not be limited thereto or thereby. Different from the structure shown in FIG. 4, at least one selected from among the hole transport region HTR, the electron transport region ETR, and the second electrode CE may be provided in the pixel openings OH defined through the pixel definition layer PDL after being patterned. As an example, according to an embodiment, at least one selected from among the hole transport region HTR, the light emitting layers EML-R, EML-G, and EML-B, the electron transport region ETR, and the second electrode CE of the light emitting elements ED-R, ED-G, and ED-B may be patterned by an inkjet printing method.

According to an embodiment, the light emitting elements ED-R, ED-G, and ED-B of the display device DD may emit lights having different wavelength ranges from each other. As an example, the display device DD may include the first light emitting element ED-R that emits a red light, the second light emitting element ED-G that emits a green light, and the third light emitting element ED-B that emits a blue light. However, the present disclosure should not be limited thereto or thereby, and the first, second, and third light emitting elements ED-R, ED-G, and ED-B may emit lights having the same wavelength range as each other, or at least one selected from among the first, second, and third light emitting elements ED-R, ED-G, and ED-B may emit a light having a wavelength range different from the other. As an example, all the first, second, and third light emitting elements ED-R, ED-G, and ED-B may emit the blue light.

In the first, second, and third light emitting elements ED-R, ED-G, and ED-B, the first electrodes AE-R, AE-G, and AE-B may be on the circuit layer DP-CL. The first electrodes AE-R, AE-G, and AE-B may be an anode or a cathode. In some embodiments, the first electrodes AE-R, AE-G, and AE-B may be a pixel electrode. The first electrodes AE-R, AE-G, and AE-B may be a transmissive electrode, a transflective electrode, or a reflective electrode.

The hole transport region HTR may be between the first electrodes AE-R, AE-G, and AE-B and the light emitting layers EML-R, EML-G, and EML-B. The hole transport region HTR may include at least one selected from among a hole injection layer, a hole transport layer, and an electron blocking layer. The hole transport region HTR may be commonly provided to overlap the display area AA, however, the present disclosure should not be limited thereto or thereby. According to an embodiment, the hole transport region HTR may be patterned into a plurality of portions to respectively correspond to the first, second, and third light emitting elements ED-R, ED-G, and ED-B.

The light emitting layers EML-R, EML-G, and EML-B may be on the first electrodes AE-R, AE-G, and AE-B. The light emitting layers EML-R, EML-G, and EML-B may include a first light emitting layer EML-R, a second light emitting layer EML-G, and a third light emitting layer EML-B. The first light emitting layer EML-R may emit a first light. The second light emitting layer EML-G may emit a second light. The third light emitting layers EML-B may emit a third light. The first, second, and third lights respectively emitted from the light emitting elements ED-R, ED-G, and ED-B may have different wavelength ranges from each other. As an example, the first light may be the red light within a wavelength range equal to or greater than about 625 nm and equal to or smaller than about 675 nm, the second light may be the green light within a wavelength range equal to or greater than about 500 nm and equal to or smaller than about 570 nm, and the third light may be the blue light within a wavelength range equal to or greater than about 410 nm and equal to or smaller than about 480 nm.

The electron transport region ETR may be between the light emitting layers EML-R, EML-G, and EML-B and the second electrode CE. The electron transport region ETR may include at least one selected from among an electron injection layer, an electron transport layer, and a hole blocking layer. The electron transport region ETR may be commonly provided to overlap the display area AA, however, the present disclosure should not be limited thereto or thereby. According to an embodiment, the electron transport region ETR may be patterned into a plurality of portions to respectively correspond to the light emitting layers EML-R, EML-G, and EML-B.

The second electrode CE may be on the electron transport region ETR. The second electrode CE may be a common electrode. The second electrode CE may be the cathode or the anode, however, the present disclosure should not be limited thereto or thereby. As an example, when the first electrodes AE-R, AE-G, and AE-B are the anode, the second electrode CE may be the cathode, and when the first electrodes AE-R, AE-G, and AE-B are the cathode, the second electrode CE may be the anode. The second electrode CE may be a transmissive electrode, a transflective electrode, or a reflective electrode.

The display device DD may further include a first dam pattern DMP1 and a second dam pattern DMP2. Each of the first dam pattern DMP1 and the second dam pattern DMP2 may be an insulating pattern (e.g., an electrically insulating patter). Each of the first dam pattern DMP1 and the second dam pattern DMP2 may have a thickness greater than a thickness of the pixel definition layer PDL. Each of the first dam pattern DMP1 and the second dam pattern DMP2 may include the same material as the pixel definition layer PDL. The first dam pattern DMP1 and the second dam pattern DMP2 may be provided in the peripheral area NAA. The first dam pattern DMP1 may be between the second dam pattern DMP2 and the first display area AA1. In some embodiments, the first dam pattern DMP1 may surround the first display area AA1 when viewed in the plane (e.g., in a plan view).

The display device DD may further include a first inorganic layer IOL1, an organic layer OL, a second inorganic layer IOL2, and a capping layer CPL.

The first inorganic layer IOL1 may be on the display element layer DP-OLED. The first inorganic layer IOL1 may extend to the peripheral area NAA. The first inorganic layer IOL1 may be on the first dam pattern DMP1 and the second dam pattern DMP2. The first inorganic layer IOL1 may cover a step difference or a curved portion caused by the display element layer DP-OLED. The first inorganic layer IOL1 may protect the light emitting elements ED-R, ED-G, and ED-B from oxygen and moisture. The first inorganic layer IOL1 may include silicon nitride and/or silicon oxynitride. The first inorganic layer IOL1 may have a thickness of about 7000 angstroms to about 1.2 micrometers. As an example, the thickness of the first inorganic layer IOL1 may be within a range from about 9000 angstroms to about 1 micrometer. The first inorganic layer IOL1 may have a single-layer structure of an inorganic layer or a multi-layer structure of a plurality of sub-inorganic layers stacked in the third direction DR3.

The organic layer OL may cover the step difference caused by the display element layer DP-OLED. The organic layer OL may overlap the display area AA. A portion of the organic layer OL may overlap the peripheral area NAA. The portion of the organic layer OL may be provided above the first dam pattern DMP1 and the second dam pattern DMP2. The organic layer OL may be on the display element layer DP-OLED. The organic layer OL may provide a base surface on which the color filters CF-R, CF-G, and CF-B, the refractive layer RL, and the protective layer PL are provided. The organic layer OL may serve as a buffer between the first inorganic layer IOL1 and the second inorganic layer IOL2. For example, the organic layer OL may relieve an interlayer stress. The organic layer OL may include a monomer and/or a polymer. The organic layer OL may have a thickness of about 6 micrometers to about 12 micrometers. As an example, the thickness of the organic layer OL may be within a range from about 8.5 micrometers to about 11 micrometers. In some embodiments, the organic layer OL may relieve stress between layers that are in contact with each other. The organic layer OL may be formed by a solution process such as a spin coating process, a slit coating process, an inkjet process, etc.

The second inorganic layer IOL2 may be on the organic layer OL to cover the organic layer OL. As the second inorganic layer IOL2 is on the organic layer OL, the second inorganic layer IOL2 may be stably formed on a relatively flat surface. The second inorganic layer IOL2 may prevent or reduce entrance or penetration of moisture and/or oxygen into the organic layer OL. The second inorganic layer IOL2 may include silicon nitride, silicon oxide, or a combination thereof. The second inorganic layer IOL2 may have a single-layer structure of an inorganic layer or a multi-layer structure of a plurality of sub-inorganic layers stacked in the third direction DR3. The capping layer CPL may be on the second inorganic layer IOL2 and

may cover the second inorganic layer IOL2. The capping layer CPL may have a single-layer or multi-layer structure. According to an embodiment, the capping layer CPL may be an organic layer and/or an inorganic layer. As an example, in a case where the capping layer CPL includes an inorganic material, the inorganic material may include SiON, SiNₓ, SiO_{y}, an alkali metal compound, such as LiF, an alkaline earth metal compound, such as MgF₂, and/or the like. As an example, in a case where the capping layer CPL includes an organic material, the organic material may include α-NPD, NPB, TPD, m-MTDATA, Alq₃, CuPc, TPD15 (N4,N4,N4′,N4′-tetra (biphenyl-4-yl) biphenyl-4,4′-diamine), TCTA (4,4′,4″-Tris (carbazol-9-yl) triphenylamine), and/or the like and/or may include an epoxy resin and/or an acrylate, such as methacrylate, however, it should not be limited thereto or thereby.

The color filters CF-R, CF-G, and CF-B may be above the display element layer DP-OLED. The color filters CF-R, CF-G, and CF-B may be on the second inorganic layer IOL2. The capping layer CPL may cover the color filters CF-R, CF-G, and CF-B. The color filters CF-R, CF-G, and CF-B may overlap the display area AA when viewed in the plane (e.g., in a plan view). The color filters CF-R, CF-G, and CF-B may include a first color filter CF-R, a second color filter CF-G, and a third color filter CF-B. The first color filter CF-R may overlap the first light emitting element ED-R when viewed in the plane (e.g., in a plan view). The second color filter CF-G may overlap the second light emitting element ED-G when viewed in the plane (e.g., in a plan view). The third color filter CF-B may overlap the third light emitting element ED-B when viewed in the plane (e.g., in a plan view). The display device DD may further include a light blocking part provided at at least one position between the first color filter CF-R and the second color filter CF-G and between the second color filter CF-G and the third color filter CF-B. The light blocking part may be a black matrix. The light blocking part may include an organic and/or inorganic light blocking material containing a black pigment and/or dye. The light blocking part may prevent or reduce a light leakage phenomenon and may be used to distinguish boundaries between the color filters CF-R, CF-G, and CF-B adjacent to each other. Each of the first, second, and third color filters CF-R, CF-G, and CF-B may include a polymer photosensitive resin and a colorant. In embodiments of the present disclosure, the colorant may include a pigment and a dye. A red colorant may include a red pigment and a red dye, a green colorant may include a green pigment and a green dye, and a blue colorant may include a blue pigment and a blue dye. The first color filter CF-R may include the red pigment and/or the red dye, the second color filter CF-G may include the green pigment and/or the green dye, and the third color filter CF-B may include the blue pigment and/or the blue dye. For example, the first color filter CF-R on the first light emitting element ED-R may include the red colorant, the second color filter CF-G on the second light emitting element ED-G may include the green colorant, and the third color filter CF-B on the third light emitting element ED-B may include the blue colorant.

The refractive layer RL may be on the color filters CF-R, CF-G, and CF-B. The refractive layer RL may overlap the display area AA when viewed in the plane (e.g., in a plan view). The refractive layer RL may include a cover layer CVL and a convex pattern ML. The refractive layer RL may allow the lights emitted from the light emitting elements ED-R, ED-G, and ED-B to travel to the third direction DR3, and thus, a front luminance rate of the display device DD may be improved. The front luminance rate may be determined by a rate of an amount of light traveling to a front side of the display device DD from a set or certain light emitting element with respect to a total amount of light generated from the set or certain light emitting element, and the expression “the front luminance rate is improved” may be interpreted as an increase in the front luminance rate. In embodiments of the present disclosure, the front side may indicate a surface facing the third direction DR3, however, this is a relative concept and the front side may be either the first direction DR1 or the second direction DR2.

The refractive layer RL may have a refractive index equal to or greater than about 1.6. The refractive layer RL may include an acryl resin. As an example, the refractive layer RL may include at least one selected from among polymethylmethacrylate, polyacrylonitrile, and polyacrylic acid. The cover layer CVL may cover the color filters CF-R, CF-G, and CF-B. The cover layer CVL may be directly on the capping layer CPL. The cover layer CVL may cover a step difference caused by the color filters CF-R, CF-G, and CF-B and may planarize an upper portion thereof.

The convex pattern ML may be between the cover layer CVL and the protective layer PL. The convex pattern ML may be provided integrally with the cover layer CVL. The convex pattern ML may have a convex shape protruding from an upper surface of the cover layer CVL to the third direction DR3. The convex pattern ML may overlap the light emitting elements ED-R, ED-G, and ED-B when viewed in the plane (e.g., in a plan view). The convex pattern ML may allow the lights emitted from the light emitting elements ED-R, ED-G, and ED-B to travel to the front side, and thus, the front luminance rate may be improved. The convex pattern ML may include a plurality of convex patterns ML-R, ML-G, and ML-B. The convex pattern ML may include a first convex pattern ML-R corresponding to the first light emitting element ED-R, a second convex pattern ML-G corresponding to the second light emitting element ED-G, and a third convex pattern ML-B corresponding to the third light emitting element ED-B. The convex pattern ML may include a micro lens.

The protective layer PL may be on the refractive layer RL. The protective layer PL may protect the convex pattern ML from physical impacts from the outside, oxygen, and/or moisture. The protective layer PL may be on the refractive layer RL and may planarize an upper surface thereof. One end of the protective layer PL may be aligned with a boundary between the display area AA and the peripheral area NAA. The protective layer PL may have a thickness d equal to or greater than about 20 micrometers and equal to or smaller than about 500 micrometers. The protective layer PL may include a first compound containing at least one selected from among a polysilsesquioxane-based compound, a polyurethane-based compound, a polycarbonate-based compound, and a polyethylene terephthalate-based compound, a second compound containing a surfactant containing at least one selected from among a fluorine-containing compound and a silicon-containing compound, and a third compound containing an epoxy-based compound. A weight of the second compound is about 0.05% or more but less than 0.2% of a sum of a weight of the first compound, a weight of the second compound, and a weight of the third compound. As an example, the weight of the second compound is about 0.05% or more and about 0.1% or less of the sum of the weight of the first compound, the weight of the second compound, and the weight of the third compound.

A young's modulus value of the protective layer PL may increase by the first compound, and thus, an impact resistance of the protective layer PL may be improved.

The first compound may include at least one selected from among a first polysilsesquioxane-based compound to a seventh polysilsesquioxane-based compound respectively represented by the following Formula 1 to Formula 7.

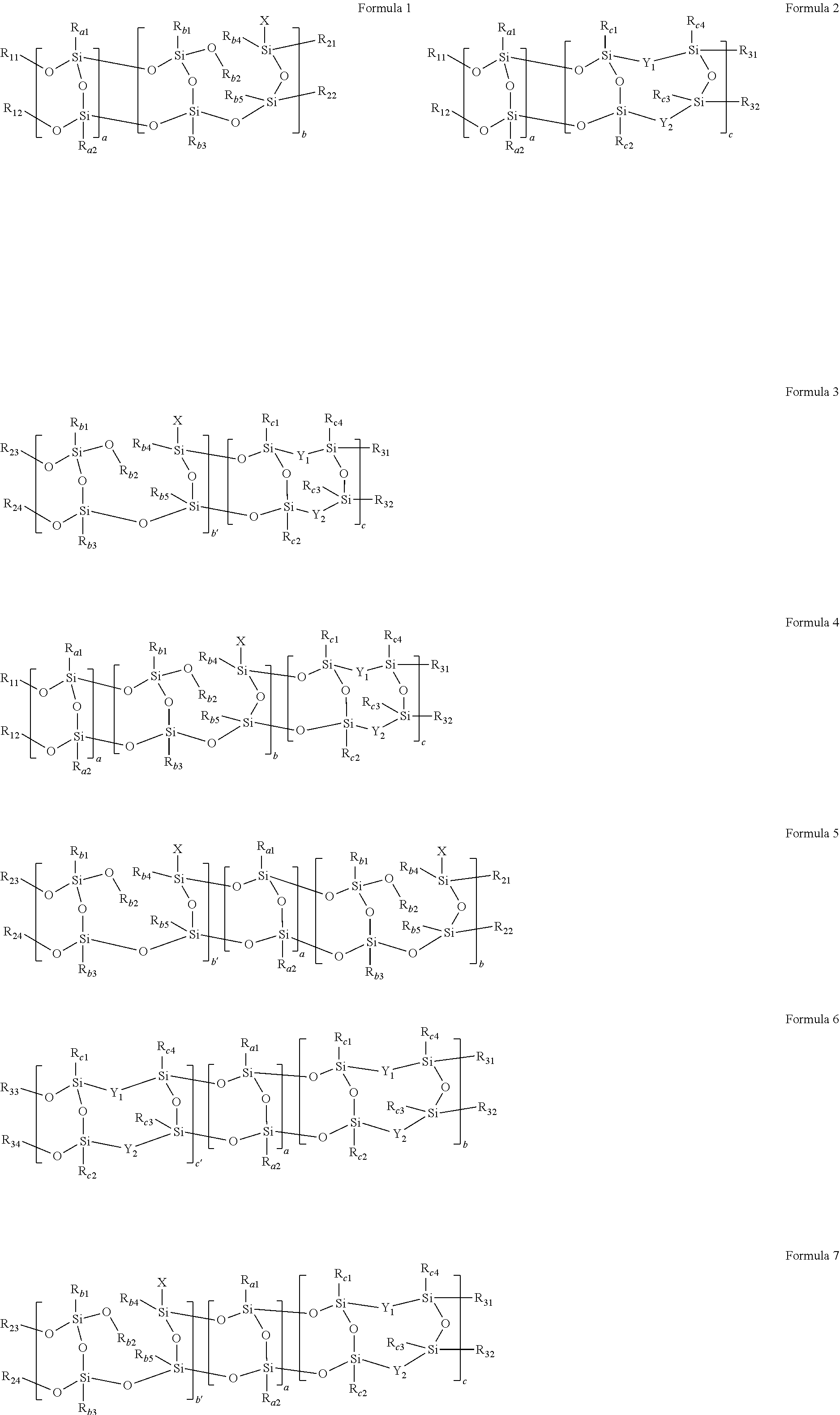

In Formula 1 to Formula 7, X is R₄₁ or [SiO_{3/2}R_{42 4+2n}O], Y₁ and Y₂ are each independently O, NR₅₁, or [SiO_{3/2}R_{52 4+2n′}O], and R₁₁, R₁₂, R₂₁ to R₂₄, R₃₁ to R₃₄, Rₐ₁, Rₐ₂, R_{b1} to R_{b5}, R_{c1} to R_{c4}, R₄₁, R₄₂, R₅₁, and R₅₂ are each independently a hydrogen atom, a deuterium atom, a halogen atom, a substituted or unsubstituted amino group, a substituted or unsubstituted epoxy group, a nitro group, a nitrile group, a thiol group, an isocyanate group, a substituted or unsubstituted alkyl group with 1 or more carbon atoms to 20 or less carbon atoms, a substituted or unsubstituted alkenyl group with 2 or more carbon atoms to 20 or less carbon atoms, a substituted or unsubstituted alkoxy group with 1 or more carbon atoms to 40 or less carbon atoms, a substituted or unsubstituted heterocyclic group with 2 or more ring-forming carbon atoms to 30 or less ring-forming carbon atoms, a substituted or unsubstituted aryl group with 6 or more ring-forming carbon atoms to 30 or less ring-forming carbon atoms, a substituted or unsubstituted heteroaryl group with 2 or more ring-forming carbon atoms to 30 or less ring-forming carbon atoms, a substituted or unsubstituted aryloxy group with 3 or more ring-forming carbon atoms to 30 or less ring-forming carbon atoms, or a substituted or unsubstituted arylthiol group with 3 or more ring-forming carbon atoms to 30 or less ring-forming carbon atoms. In embodiments of the present disclosure, the substituted alkyl group may be a functional group including an alkyl group in which an aryl group is substituted and a cycloalkyl group. X is, for example, [SiO_{3/2}R_{42 4+2n}O], and each of Y₁ and Y₂ is [SiO_{3/2}R_{52 4+2n′}O]. R₁₁, R₁₂, R₂₁ to R₂₄, R₃₁ to R₃₄, Rₐ₁, Rₐ₂, R_{b1} to R_{b5}, R_{c1} to R_{c4}, R₄₁, R₄₂, R₅₁, and R₅₂ are each an unsubstituted methyl group.

In embodiments of the present disclosure, n and n′ may each independently be an integer equal to or greater than 1 and equal to or smaller than 20. As an example, each of n and n′ may be 10.

In embodiments of the present disclosure, a may be an integer equal to or greater than 1 and equal to or smaller than 100000, and b, b′, c, and c′ may each independently be an integer equal to or greater than 1 and equal to or smaller than 100. As an example, “a” may be 50000, and each of b, b′, c, and c′ may be 50.

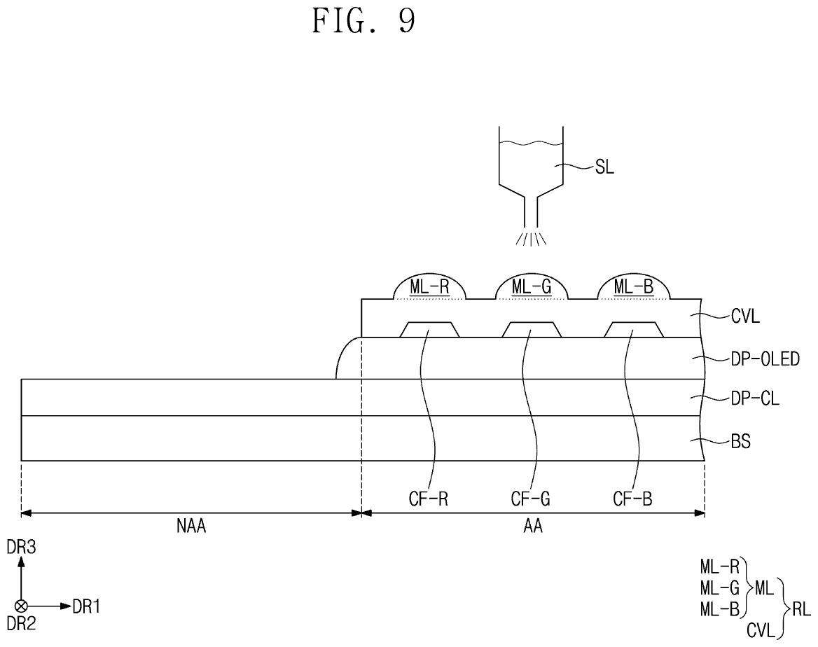

The surfactant included in the second compound may include at least one selected from among FC-4430, FC-4432, and FC-4434 manufactured by 3M Company. The second compound may allow a mixed solution SL (refer to FIG. 9), which is a material for the protective layer PL, to form a suitable or appropriate contact angle with the refractive layer RL so that one end of the protective layer PL is aligned with the boundary between the display area AA and the peripheral area NAA without additional processes in a manufacturing process of the protective layer PL. As a result, the level of difficulty and the cost-effectiveness of the manufacturing method of the display device DD may be improved (e.g., the level of difficulty may be reduced and the cost-effectiveness of the manufacturing method may be increased).

The epoxy-based compound included in the third compound may include a viscosity modifier. The viscosity modifier included in the third compound may include at least one selected from among a glycidyl ether-based compound, a glycidyl amine-based compound, a glycidyl ester-based compound, and a diepoxy-based compound. As an example, the viscosity modifier included in the third compound may be n-butyl glycidyl ether. The third compound may increase the viscosity of the mixed solution SL (refer to FIG. 9), which is the material for the protective layer PL, in the process of forming the protective layer PL to prevent or reduce separation of the mixed solution SL (refer to FIG. 9) from the refractive layer RL after being coated on the refractive layer RL. Accordingly, the reliability of the manufacturing method of the display device DD may be improved (e.g., increased).

The display device DD may further include the filling layer FM. The filling layer FM may be don the base layer BS. The filling layer FM may overlap the protective layer PL in the first direction DR1. One end of the filling layer FM may be in contact with one end of the protective layer PL. The one end of the filling layer FM may be aligned with the boundary between the display area AA and the peripheral area NAA. The filling layer FM may include an epoxy-based organic material. The filling layer FM may overlap the peripheral area NAA.

The display device DD may further include the window WM on the protective layer PL. The window WM may cover an upper outer side of the display device DD. A front surface of the window WM may correspond to a front surface of the display device DD. The window WM may include an optically transparent insulating (e.g., electrically insulating) material. The window WM may include a glass and/or plastic material. The window WM may have a single-layer or multi-layer structure. As an example, the window WM may include a plurality of plastic films attached to each other by an adhesive and/or a glass substrate and a plastic film attached to the glass substrate by an adhesive.

The display device DD may further include the sealing member SLM. The sealing member SLM may be between the base layer BS and the window WM. The protective layer PL may be spaced apart from the sealing member SLM in the first direction DR1. A space between the sealing member SLM and the protective layer PL may be filled with the filling layer FM. For example, the sealing member SLM, the filling layer FM, and the protective layer PL may be sequentially provided in the first direction DR1. In some embodiments, the sealing member SLM may be provided along an edge of the display device DD. The sealing member SLM may be aligned with the edge of the display device DD. The sealing member SLM may protect an inner portion of the display device DD from external impacts and may be between the circuit layer DP-CL and the window WM in the peripheral area NAA to support the window WM. The sealing member SLM may include a binder resin and inorganic fillers mixed with the binder resin. The sealing member SLM may further include other additives. The additives may include an amine-based curing agent and a photoinitiator. The additives may further include silane-based additives and acrylic-based additives. The sealing member SLM may also contain an inorganic material such as frit.

Hereinafter, the manufacturing method of the display device according to embodiments of the present disclosure will be described. Detailed descriptions on the components previously described with reference to FIGS. 1 to 4 will not be repeated here.

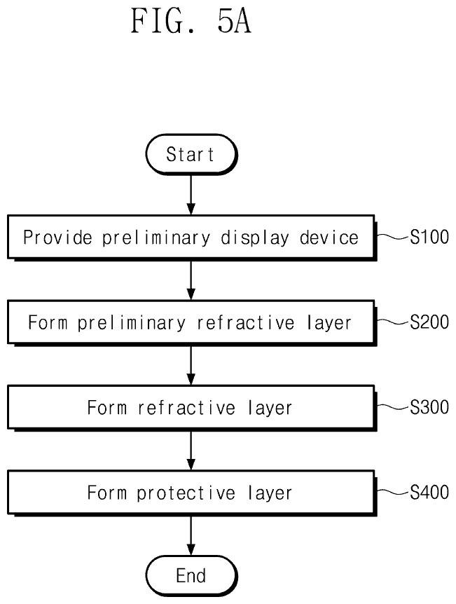

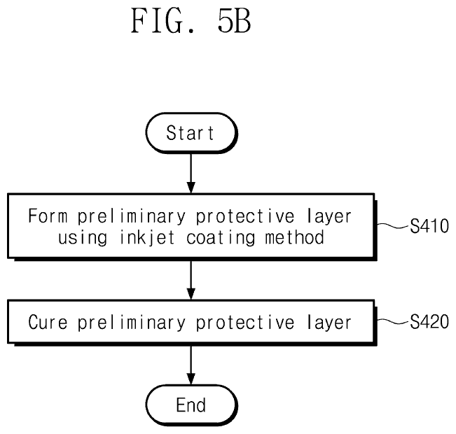

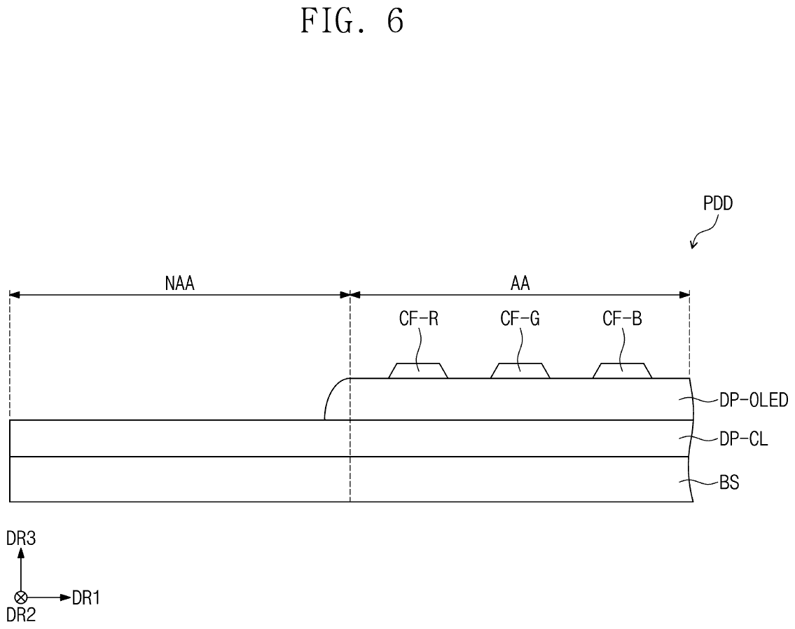

FIGS. 5A-5B are flowcharts illustrating the manufacturing method of the display device according to an embodiment of the present disclosure. FIGS. 6-11 are cross-sectional views illustrating processes of the manufacturing method of the display device according to an embodiment of the present disclosure.

Referring to FIGS. 5A-5B, the manufacturing method of the display device may include providing a preliminary display device (S100), providing a preliminary refractive layer (S200), forming the refractive layer (S300), and forming the protective layer (S400). The forming of the protective layer (S400) may include forming a preliminary protective layer using an inkjet coating method (S410) and curing the preliminary protective layer (S420).

Referring to FIG. 6, the preliminary display device PDD includes the display area AA and the peripheral area NAA adjacent to the display area AA and includes the base layer BS, the display element layer DP-OLED on the base layer BS and including the light emitting element overlapping the display area AA when viewed in the plane (e.g., in a plan view), and the color filters CF-R, CF-G, and CF-B on the display element layer DP-OLED in the providing of the preliminary display device PDD. The preliminary display device PDD does not include the refractive layer RL (refer to FIG. 3) and the protective layer PL (refer to FIG. 3) compared with the display device DD (refer to FIG. 3).

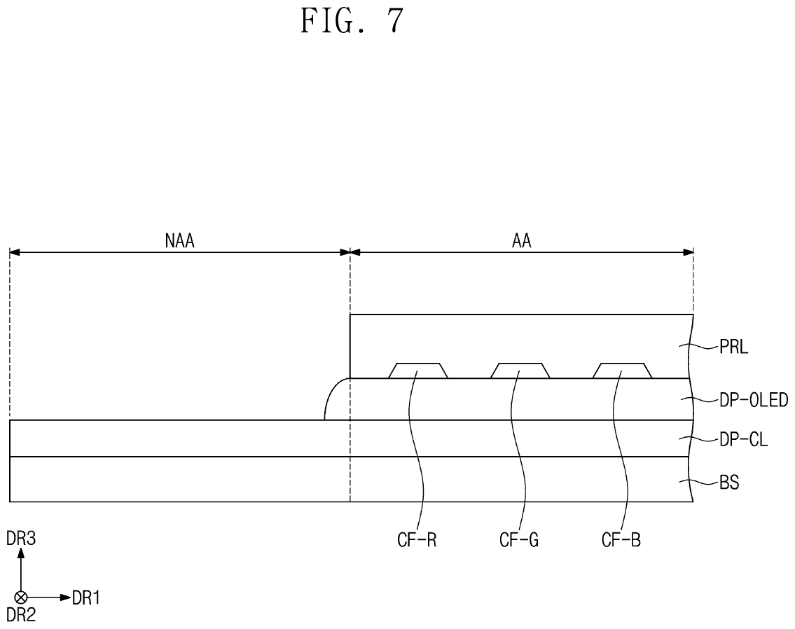

Referring to FIGS. 6-7, the preliminary refractive layer PRL is formed on the color filters CF-R, CF-G, and CF-B in the forming of the preliminary refractive layer PRL. The preliminary refractive layer PRL covers the color filters CF-R, CF-G, and CF-B. The preliminary refractive layer PRL may be deposited by the solution process such as spin coating, slit coating, and/or inkjet processes. As an example, the preliminary refractive layer PRL may be formed by the inkjet process. The preliminary refractive layer PRL may have the young's modulus equal to or greater than about 1 GPa and equal to or smaller than about 10 GPa at about 25 degrees Celsius. As an example, the young's modulus of the preliminary refractive layer PRL may be equal to or greater than about 1 GPa and equal to or smaller than about 10 GPa at about 5 degrees Celsius.

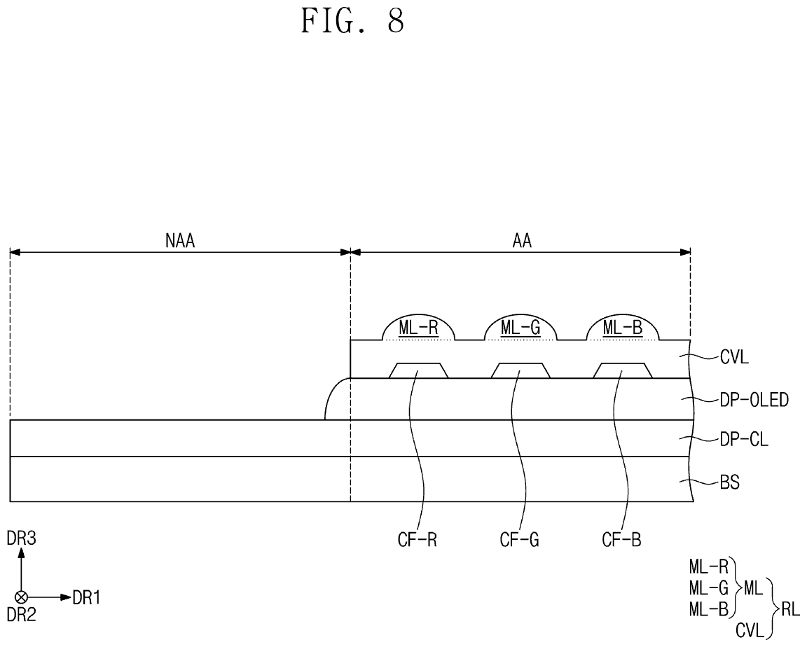

Referring to FIGS. 7-8, the refractive layer RL may be formed by etching a portion of the preliminary refractive layer PRL in the forming of the refractive layer RL. The process of etching the preliminary refractive layer PRL may include a dry etching process, a wet etching process, and/or a photoresist process. As an example, the preliminary refractive layer PRL may be etched by the photoresist process.

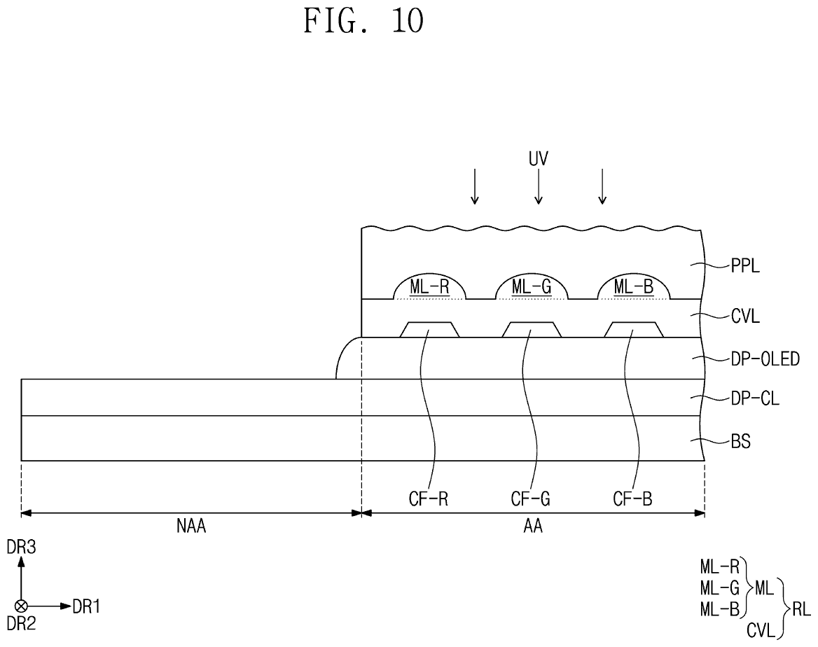

Referring to FIGS. 9-10, in the forming of the preliminary protective layer PPL using the inkjet coating method, the preliminary protective layer PPL may be formed by coating the mixed solution SL including the first compound, the second compound, and the third compound on the refractive layer RL using the inkjet coating method. The preliminary protective layer PPL may have a viscosity of about 1 cP or more and about 30 cP or less at about 20 degrees Celsius. As an example, the viscosity of the preliminary protective layer PPL may be about 15 cP at about 20 degrees Celsius. When the viscosity of the preliminary protective layer PPL is within a range of about 1 cP or more and about 30 cP or less at about 20 degrees Celsius, the preliminary protective layer PPL does not spread excessively when being in contact with the refractive layer RL, allowing one end of the protective layer PL to be aligned with the boundary between the display area AA and the peripheral area NAA without additional processes, and thus, the level of difficulty and the cost-effectiveness of the manufacturing method of the display device DD may be improved (e.g., the level of difficulty may be reduced and the cost-effectiveness may be increased).

The weight of the second compound is about 0.05% or more but less than 0.2% of the sum of the weight of the first compound, the weight of the second compound, and the weight of the third compound in the mixed solution SL. As an example, the weight of the second compound is about 0.05% or more or about 0.1% or less of the sum of the weight of the first compound, the weight of the second compound, and the weight of the third compound. As an example, the second compound may include FC-4430 manufactured by 3M Company.

Table 1 below shows contact angles measured by applying about 1.5 microliters of each of a deionized water (DI), solution 1, which is a mixture of polyhedral oligomeric silsesquioxane (POSS) and FC-4430 at 0.1% by weight (based on a total weight), and solution 2, which is a mixture of polyhedral oligomeric silsesquioxane (POSS) and FC-4430 at 0.2% by weight (based on the total weight) on each of a glass substrate and an acrylic resin substrate. When the contact angle with the acrylic resin substrate is equal to or greater than about 20 degrees and equal to or smaller than about 30 degrees, the spreadability of the applied solution is evaluated as excellent. In embodiments of the present disclosure, the term “excellent spreadability” means that, on a target substrate including a first surface and a second surface relatively higher than the first surface, the solution does not overflow onto the first surface when the solution is applied only to the second surface, or the contact area between the solution and the second surface does not decrease after 3 minutes from the initial application of the solution.

TABLE 1

| | Deionized water | Solution 1 | Solution 2 |
|---|---|---|---|
| Glass substrate | 110.3 degrees | 41.9 degrees | 35.8 degrees |
| Acrylic resin | 137.1 degrees | 26.9 degrees | 18.1 degrees |
| substrate | | | |

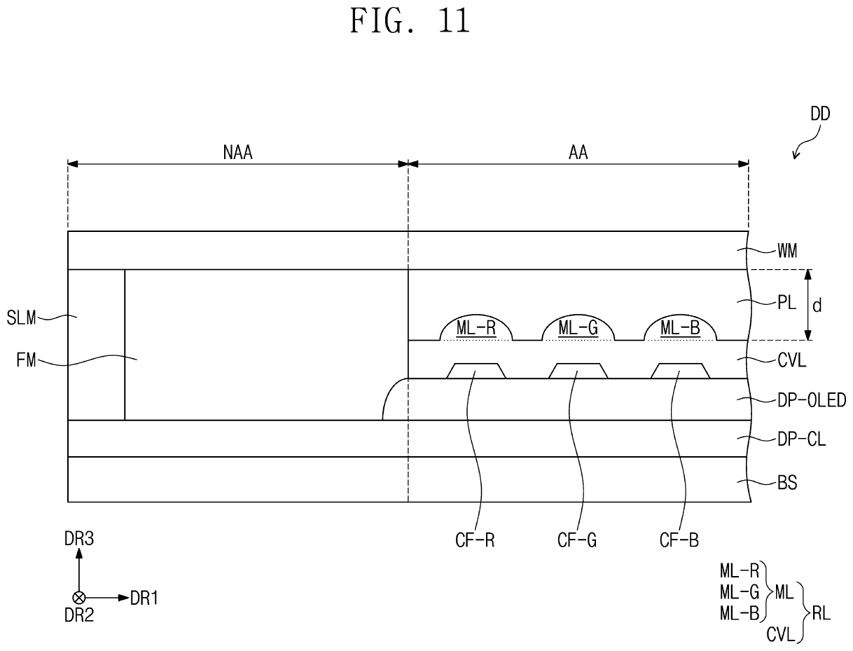

Referring to Table 1, each of solution 1 and solution 2 has a smaller contact angle than that of the deionized water, so that the area in contact with each of the glass substrate and the acrylic resin substrate does not become excessively wide. Solution 1 has a greater contact angle for each of the glass substrate and the acrylic resin substrate than solution 2, and, for example, because solution 1 has the contact angle of about 26.9 degrees for the acrylic resin substrate, solution 1 has better spreadability than solution 2. This is believed to because a weight ratio of FC-4430, which is a surfactant in solution 1, is about 0.05% by weight or more and less than about 0.2% by weight, which is the range where the spreadability of solution 1 may be improved. Referring to FIGS. 10-11, the preliminary protective layer PPL may be cured by an ultraviolet ray (UV) in the curing of the preliminary protective layer PPL to form the protective layer PL.

Different from the preliminary protective layer of embodiments of the present disclosure, another preliminary protective layer does not include the first to third compounds. Accordingly, the contact angle with the refractive layer exceeds 30 degrees, and thus the contact area between the refractive layer and the preliminary protective layer decreases, or the contact angle with the refractive layer is smaller than 20 degrees, and thus the preliminary protective layer is formed on other components in addition to the refractive layer. According to the forming of the protective layer PL in the manufacturing method of the display device according to embodiments of the present disclosure, the preliminary protective layer PPL formed by the inkjet coating method includes the mixed solution SL containing the first to third compounds, and the contact angle with the refractive layer RL may be equal to or greater than about 20 degrees and equal to or smaller than about 30 degrees, thereby improving the spreadability.

After the forming of the protective layer PL, the manufacturing method of the display device DD may further include forming the sealing member SLM on the base layer BS, forming the filling layer FM between the sealing member SLM and the protective layer PL, and forming the window WM on the sealing member SLM, the filling layer FM, and the protective layer PL.

Although embodiments of the present disclosure have been described, it should be understood that embodiments of the present disclosure should not be limited to these embodiments but various suitable changes and modifications can be made by one having ordinary skill in the art within the spirit and scope of the present disclosure as hereinafter claimed. Therefore, the disclosed subject matter should not be limited to any single embodiment described herein, and the scope of the present disclosure shall be determined according to the attached claims, and equivalents thereof.

What is claimed is:

1. An electronic apparatus, the electronic apparatus comprising:
a display area and a peripheral area disposed adjacent to the display area;
a base layer;
a display element layer on the base layer and comprising a light emitting element that overlaps the display area when viewed in a plane;
a color filter on the display element layer;
a refractive layer on the color filter; and
a protective layer on the refractive layer, the refractive layer comprising:
a cover layer that covers the color filter; and
a convex pattern between the cover layer and the protective layer and provided integrally with the cover layer, wherein one end of the protective layer is aligned with a boundary between the display area and the peripheral area when viewed in the plane.

2. The electronic apparatus as claimed in claim 1, further comprising a filling layer disposed on the base layer and overlapping the protective layer in a first direction.

3. The electronic apparatus as claimed in claim 2, wherein the filling layer is in contact with the one end of the protective layer.

4. The electronic apparatus as claimed in claim 1, wherein the protective layer has a thickness equal to or greater than about 20 micrometers and equal to or smaller than about 500 micrometers.

5. The electronic apparatus as claimed in claim 1, further comprising: a window disposed on the protective layer; and
a sealing member disposed between the base layer and the window, wherein the protective layer is spaced apart from the sealing member in a first direction.

6. The electronic apparatus as claimed in claim 1, wherein the convex pattern overlaps the light emitting element when viewed in the plane.

7. The electronic apparatus as claimed in claim 1, wherein the light emitting element is provided in plural, and the convex pattern is provided in plural.

8. The electronic apparatus as claimed in claim 1, wherein the refractive layer has a refractive index equal to or greater than about 1.6, and
wherein the refractive layer comprises an acrylic resin.

9. The electronic apparatus as claimed in claim 1, wherein the display area comprises a first display area and a second display area spaced apart from the first display area when viewed in the plane, and each of the first and second display areas has a quadrangular shape or a circular shape.

10. The electronic apparatus as claimed in claim 1, wherein the light emitting element comprises a first electrode, a light emitting layer disposed on the first electrode, and a second electrode disposed on the light emitting layer.

11. The electronic apparatus as claimed in claim 1, wherein the electronic apparatus is a head-mounted display (HMD).

12. An electronic apparatus, the electronic apparatus comprising:
a display area and a peripheral area disposed adjacent to the display area;
a base layer;
a display element layer on the base layer and comprising a light emitting element that overlaps the display area when viewed in a plane;
a color filter on the display element layer;
a refractive layer on the color filter; and
a protective layer on the refractive layer, the refractive layer comprising:
a cover layer that covers the color filter; and
a convex pattern between the cover layer and the protective layer and provided integrally with the cover layer, wherein the protective layer comprises:
a first compound comprising at least one selected from among a polysilsesquioxane-based compound, a polyurethane-based compound, a polycarbonate-based compound, and a polyethylene terephthalate-based compound;
a second compound comprising a surfactant comprising at least one selected from among a fluorine-containing compound and a silicon-containing compound; and
a third compound comprising an epoxy-based compound, and a weight of the second compound is about 0.05% or more but less than 0.2% of a sum of a weight of the first compound, the weight of the second compound, and a weight of the third compound.

13. The electronic apparatus as claimed in claim 12, wherein one end of the protective layer is aligned with a boundary between the display area and the peripheral area when viewed in the plane.

14. The electronic apparatus as claimed in claim 12, wherein the first compound comprises at least one selected from among a first polysilsesquioxane-based compound to a seventh polysilsesquioxane-based compound respectively represented by the following Formula 1 to Formula 7, 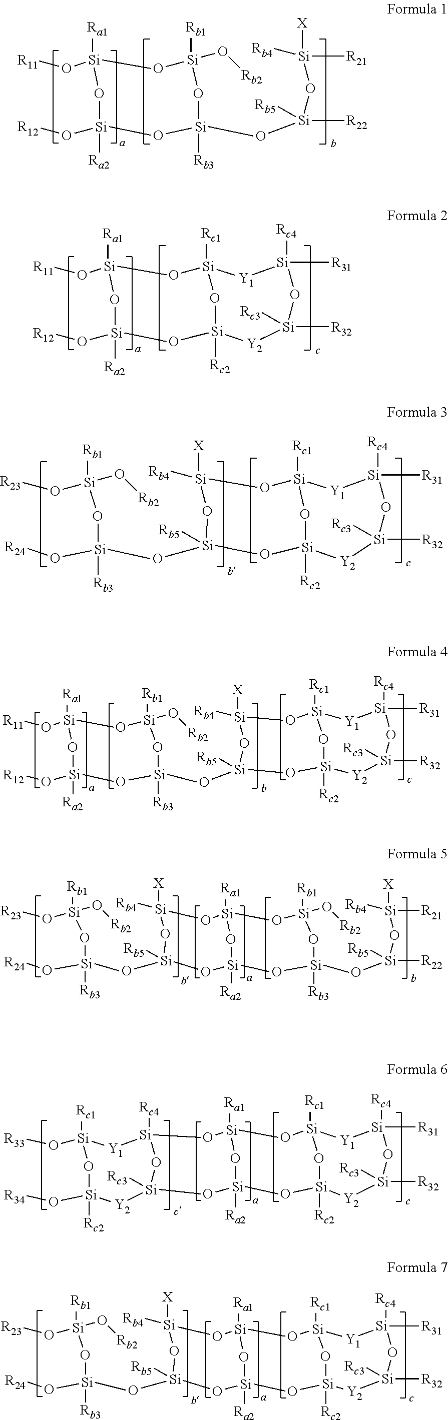
wherein, in Formula 1 to Formula 7,
X is R₄₁ or [SiO_{3/2}R_{42 4+2n}O],
Y₁ and Y₂ are each independently O, NR₅₁, or [SiO_{3/2}R_{52 4+2n′}O],
R₁₁, R₁₂, R₂₁ to R₂₄, R₃₁ to R₃₄, Rₐ₁, Rₐ₂, R_{b1} to R_{b5}, R_{c1} to R_{c4}, R₄₁, R₄₂, R₅₁, and R₅₂ are each independently a hydrogen atom, a deuterium atom, a halogen atom, a substituted or unsubstituted amino group, a substituted or unsubstituted epoxy group, a nitro group, a nitrile group, a thiol group, an isocyanate group, a substituted or unsubstituted alkyl group having 1 to 20 carbon atoms, a substituted or unsubstituted alkenyl group having 2 to 20 carbon atoms, a substituted or unsubstituted alkoxy group having 1 to 40 carbon atoms, a substituted or unsubstituted heterocyclic group having 2 to 30 ring-forming carbon atoms, a substituted or unsubstituted aryl group having 6 to 30 ring-forming carbon atoms, a substituted or unsubstituted heteroaryl group having 2 to 30 ring-forming carbon atoms, a substituted or unsubstituted aryloxy group having 3 to 30 ring-forming carbon atoms, or a substituted or unsubstituted arylthiol group having 3 to 30 ring-forming carbon atoms,
n and n′ are each independently an integer equal to or greater than 1 and equal to or smaller than 20,
a is an integer equal to or greater than 1 and equal to or smaller than 100000, and
b, b′, c, and c′ are each independently an integer equal to or greater than 1 and equal to or smaller than 100.

15. The electronic apparatus as claimed in claim 12, wherein the epoxy-based compound comprises a viscosity modifier.

16. A method of manufacturing an electronic apparatus, the method comprising:
providing a preliminary display device comprising a display area and a peripheral area adjacent to the display area and comprising a base layer, a display element layer on the base layer and comprising a light emitting element overlapping the display area when viewed in a plane, and a color filter on the display element layer,
forming a preliminary refractive layer on the color filter; and
etching a portion of the preliminary refractive layer to form a refractive layer; and
forming a protective layer on the refractive layer, the refractive layer comprising:
a cover layer covering the color filter; and
a convex pattern between the cover layer and the protective layer and provided integrally with the cover layer, wherein one end of the protective layer is aligned with a boundary between the display area and the peripheral area when viewed in the plane.

17. The method as claimed in claim 16, wherein the forming of the protective layer comprises:
forming a preliminary protective layer comprising a first compound, a second compound, and a third compound using an inkjet coating method; and
curing the preliminary protective layer,
the first compound comprises at least one selected from among a polysilsesquioxane-based compound, a polyurethane-based compound, a polycarbonate-based compound, and a polyethylene terephthalate-based compound,
the second compound comprises a surfactant comprising at least one selected from among a fluorine-containing compound and a silicon-containing compound,
the third compound comprises an epoxy-based compound, and
a weight of the second compound is about 0.05% or more but less than 0.2% of a sum of a weight of the first compound, the weight of the second compound, and a weight of the third compound.

18. The method as claimed in claim 17, wherein the preliminary protective layer has a viscosity of about 1 cP or more and about 30 cP or less at about 20 degrees Celsius.

19. The method as claimed in claim 16, wherein the preliminary refractive layer has a young's modulus equal to or greater than about 1 GPa and equal to or smaller than about 10 GPa at about 25 degrees Celsius.

20. The method as claimed in claim 17, wherein the weight of the second compound is about 0.05% or more and about 0.1% or less of the sum of the weight of the first compound, the weight of the second compound, and the weight of the third compound.
